(19) United States
(12) Patent Application Publication
(10) Pub. No.: US 2020/0321781 A1
(43) Pub. Date: Oct. 8, 2020

(54) METHOD, SERVER, PROGRAM, AND TERMINAL FOR GENERATING INFORMATION RELATING TO ELECTRICAL OUTPUT OF SOLAR GENERATOR

(71) Applicant: Panasonic Intellectual Property Management Co.,Ltd, Osaka (JP)

(72) Inventors: Takahiro SUGIMOTO, Tokyo (JP); Kotaro SAKATA, Osaka (JP); Kazuya ITO, Saitama (JP); Takaaki YOSHIHARA, Osaka (JP); Takashi TORII, Osaka (JP)

(73) Assignees: Panasonic Intellectual Property Management Co., Ltd., Osaka (JP); Panasonic Intellectual Property Management Co., Ltd., Osaka (JP)

(21) Appl. No.: 16/303,916

(22) PCT Filed: May 16, 2017
(86) PCT No.: PCT/JP2017/018319

§ 371 Date: Nov. 21, 2018

(30) Foreign Application Priority Data
May 26, 2016 (JP) 2016-105553
Nov. 1, 2016 (JP) 2016-214722

(51) Int. Cl. H02J 3/00; G01W 1/04; G01R 21/133; H02S 50/00; H02J 3/38

(52) U.S. Cl. CPC H02J 3/004; G01W 1/04; H02J 3/381; H02S 50/00; G01R 21/133

(57) ABSTRACT

A method includes acquiring weather information relating to at least one of physical quantities including insolation, cloudiness, and humidity; performing a rating scale assessment of the weather information based on a predetermined threshold value; predicting an electrical output of a solar generator; performing a rating scale assessment of the electrical output of the solar generator based on a standard electrical output of the solar generator; and generating information indicating an assessment value obtained in the performing of the rating scale assessment of the weather information, and an assessment value obtained in the performing of the rating scale assessment of the electrical output.

### TECHNICAL FIELD

The present invention relates to a method, server, program and terminal for generating information relating to the electrical output of solar generators.

### BACKGROUND ART

Due to solar generators becoming more common, services that present the electrical output thereof to users or electrical operators are becoming more widespread as well.

Patent Literature (PTL) 1 discloses a display device that visually shows changes in climate and changes in the electric power of solar panels.

### CITATION LIST

### Patent Literature

PTL 1: Japanese Patent No. 5957740.

### SUMMARY OF THE INVENTION

### Technical Problem

The display device disclosed in PTL 1 shows actual and predicted values of the electrical output of a solar generator. The real and predicted values this display device shows are influenced by weather and placement conditions, and the like of the solar generator. Since this display device, however, does not show anything about these influences, users and the like who see the electrical output on the above display device cannot determine whether this information is correct. In this manner, the above display device has the problem of not being able to provide the user and the like with information that forms a basis for determining the validity of the shown electrical output.

The present invention aims to provide a presentation device and the like presenting information that forms a basis to determine the validity of the electrical output of a solar generator.

### Solutions to Problem

In order to achieve the above goal, a method according to a mode of the present invention includes: acquiring weather information relating to at least one of physical quantities including insolation, cloudiness, and humidity; performing a rating scale assessment of the weather information based on a predetermined threshold value; predicting an electrical output of a solar generator; performing a rating scale assessment of the electrical output of the solar generator based on a standard electrical output of the solar generator; and generating information indicating an assessment value obtained in the performing of the rating scale assessment of the weather information, and an assessment value obtained in the performing of the rating scale assessment of the electrical output.

Moreover, a server according to a mode of the present invention includes: an acquiring unit configured to acquire weather information relating to at least one of physical quantities including insolation, cloudiness, and humidity; a weather assessment unit configured to perform a rating scale assessment of the weather information based on a predetermined threshold value; a prediction unit configured to predict an electrical output of a solar generator; an electrical output assessment unit configured to perform a rating scale assessment of the electrical output of the solar generator based on a standard electrical output of the solar generator; and an information generation unit configured to generate information indicating an assessment value obtained from the rating scale assessment performed by the weather assessment unit, and an assessment value obtained from the rating scale assessment performed by the electrical output assessment unit.

Moreover, a program according to a mode of the present invention causes a computer to execute the method.

Moreover, a terminal according to a mode of the present invention includes: an acquiring unit configured to acquire weather information relating to at least one of physical quantities including insolation, cloudiness, and humidity; a weather assessment unit configured to perform a rating scale assessment of the weather information based on a predetermined threshold value; a prediction unit configured to predict an electrical output of a solar generator; an electrical output assessment unit configured to perform a rating scale assessment of the electrical output of the solar generator based on a standard electrical output of the solar generator; an information generation unit configured to generate information indicating an assessment value obtained from the rating scale assessment performed by the weather assessment unit, and an assessment value obtained from the rating scale assessment performed by the electrical output assessment unit; and a presentation unit configured to present the information generated by the information generation unit.

### Advantageous Effect of Invention

The method in the present invention makes it possible to provide information that forms a basis to determine the validity of the electrical output of a solar generator.

### BRIEF DESCRIPTION OF DRAWINGS

FIG. 1 is a block diagram showing function blocks of a presentation device according to an embodiment.

FIG. 2 is an explanatory diagram showing an example of an index calculation method by an index calculation unit according to the embodiment.

FIG. 3 is an explanatory diagram showing a first mode of an index presentation by a presentation unit according to the embodiment.

FIG. 4 is an explanatory diagram showing a second mode of the index presentation by the presentation unit according to the embodiment.

FIG. 5 is an explanatory diagram showing a third mode of the index presentation by the presentation unit according to the embodiment.

FIG. 6 is a flowchart showing a control method of the presentation device according to the embodiment.

FIG. 7 is an explanatory diagram showing another example of the index calculation method by the index calculation unit according to the embodiment.

FIG. 8 is an explanatory diagram showing the index calculation method by the index calculation unit according to Variation 1 of the embodiment.

FIG. 9 is an explanatory diagram showing a fourth mode of the index presentation by the presentation unit according to Variation 2 of the embodiment.

FIG. 10 is an explanatory diagram showing a presentation mode using index illustrations by the presentation unit according to Variation 3 of the embodiment.

FIG. 11 is an explanatory diagram showing a presentation mode using index panels by the presentation unit according to Variation 3 of the embodiment.

FIG. 12 is a first explanatory diagram showing concrete examples of the presentation mode using index illustrations by the presentation unit according to Variation 3 of the embodiment.

FIG. 13 is a second explanatory diagram showing concrete examples of the presentation mode using index illustrations by the presentation unit according to Variation 3 of the embodiment.

FIG. 14 is an explanatory diagram showing a presentation mode using an index calendar by the presentation unit according to Variation 3 of the embodiment.

FIG. 15 is a block diagram showing the function blocks of a presentation system according to Variation 4 of the embodiment.

FIG. 16 is a flowchart showing a process of the presentation system according to Variation 4 of the embodiment.

### DESCRIPTION OF EXEMPLARY EMBODIMENT

Hereinafter, a presentation device and the like according to the present embodiment will be described with reference to the drawings. Note that the embodiment and its variations described below show a specific example of the present invention. Therefore, numerical values, shapes, materials, components, placement and connection of the components, steps, the order of steps, and the like in the following embodiments are mere examples and are not intended to limit the present invention. Components in the following embodiments not mentioned in any of the independent claims that define the broadest concepts are described as optional elements. Note that the drawings are schematic diagrams and do not necessarily provide strictly accurate illustrations.

In the present disclosure, the device, all or a part of the units, or all or a part of the functions of the function blocks of the block diagrams shown in the drawings may also be executed by one or multiple electronic circuits including a semiconductor device, integrated circuit (IC), or large-scale-integrated (LSI) circuit. The LSI circuit or IC may also be formed on one chip or a combination of multiple chips. The function blocks aside from the memory element may also be formed on one chip.

Furthermore, in the present disclosure, the process designated by all or a part of the steps, or all or a part of the steps of the flowcharts shown in the drawings can also be executed using software. In this case, the software is recorded on permanent recording media such as a single ROM or multiple ROMs, an optical disc, or a hard disk drive. When the software is executed by a processor, the functions designated by the software are executed by the processor and peripheral equipment. The system or device may also include one or multiple permanent storage media that contain the software, processor, and any necessary hardware devices, such as an interface.

### Embodiment

In the present embodiment, a presentation device providing information that forms a basis to determine the validity of electrical output of a solar generator and the like will be described. Presentation device 1 of the present embodiment provides information that forms a basis for determining the validity of the electrical output by providing indices regarding a given standard electrical output of the solar generator that fluctuates due to weather and the like.

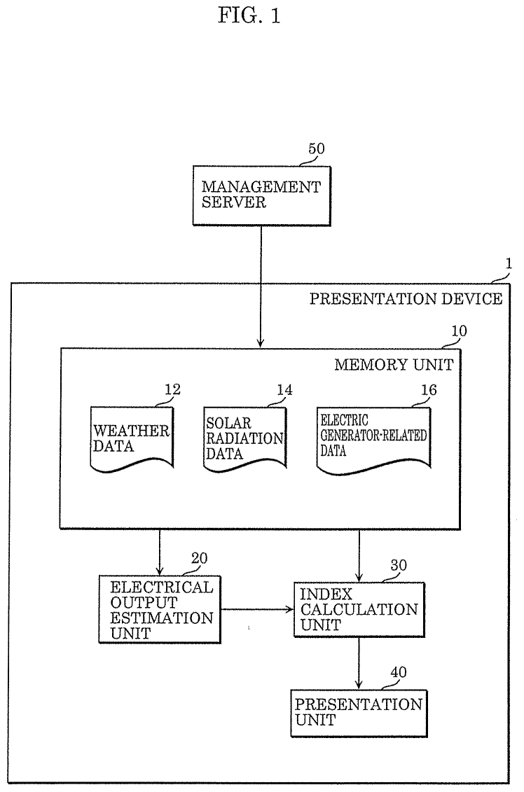

FIG. 1 is a block diagram showing the function blocks of presentation device 1 according to the present embodiment.

As illustrated in FIG. 1, presentation device 1 includes memory unit (storage) 10, electrical output estimation unit 20, index calculation unit 30, and presentation unit 40. Moreover, presentation device 1 is connected to management server 50 that manages various types of data, and the solar generator (not illustrated in the drawings) receives sunlight on solar panels to generate power. Note that presentation device 1 may be multiple devices communicably connected that divide each of the functions, or a single terminal.

Memory unit 10 contains the plurality of physical quantities indicating respective amounts of the plurality of phenomena that cause the electrical output of the solar generator to change. To be specific, memory unit 10 contains various types of information as the above physical quantities: current and past weather data 12, solar radiation data 14, and electric generator-related data 16. Weather data 12 and solar radiation data 14 are also referred to as weather information.

The various types of data contained in memory unit 10 are acquired through a communication interface (not illustrated in the drawings) by presentation device 1. Weather data 12 and solar radiation data 14 are acquired from a servicer providing weather data or management server 50 and the like that manage data provided by the servicer. Electric generator-related data 16 may be data recorded in memory unit 10 when the user purchases the solar generator, or may also be data updated according to usage of the solar generator. Note that when the time is divided into intervals of predetermined duration (for example 30 minutes), then “present” indicates the interval to which the present point in time belongs. In other words, “present” not only strictly indicates the present point in time, but also the 30-minute interval including the present point in time. This also applies hereinafter.

Note that the phenomena that cause the electrical output to change include phenomena that cause the electrical output to decrease and phenomena that cause the electrical input to increase. The phenomena that cause the electrical output to decrease include, for example, clouds covering the sky (i.e., the amount of clouds covering the sky increases), or moisture in the air (i.e., moisture in the air increases). Moreover, the phenomena that cause the electrical output to decrease can also be called the opposite of phenomena that cause the electrical output to increase. For example, “the amount of clouds covering the sky decreases” can be called a phenomenon that causes the electrical output to increase, but this is also the opposite of a phenomenon that causes the electrical output to decrease, as in the opposite of “the amount of clouds covering the sky increases”. In other words, phenomena that cause the electrical output to increase can be used as the opposite of the above “phenomena causing the electrical output to decrease”.

Weather data 12 is data of a predetermined time period, and includes, to be more specific, cloudiness, humidity, temperature, wind speed, wind direction, precipitation rate, or atmospheric pressure data of a current or past predetermined time period. Cloudiness includes total cloudiness, high-level cloudiness, mid-level cloudiness, or low-level cloudiness. For example, the physical quantity cloudiness indicates the amount of clouds covering the sky, and the physical quantity humidity indicates the amount of moisture in the air.

Above-mentioned weather data 12 includes the above various types of data in intervals of a predetermined duration (for example 30 minutes). Weather data 12 is, for example, data of a location where the solar generator is set up obtained from weather data maintained by the Japan Meteorological Agency (JMA). Note that hereinafter, weather data 12 will be explained using cloudiness and humidity as examples.

Solar radiation data 14 includes data of a past predetermined time period. Solar radiation data 14 includes insolation data of present and past predetermined durations (for example 30 minutes). Solar radiation data 14 includes a record of the amount of sunlight radiated on the solar generator in the past, and the amount of sunlight currently being radiated thereon. Note that the past data of solar radiation data 14 may also be calculated from the amount of sunlight radiated on the solar generator in the past based on the standardized solar radiation data per region maintained by the JMA. This depends on whether the insolation at a given location and time during clear weather can theoretically be calculated. In other words, the past data of solar radiation data 14 may be calculated from standard solar radiation data. Moreover, the insolation during clear weather calculated theoretically may also be used for the past, current, or future data of solar radiation data 14.

Electric generator-related data 16 is data related to the solar generator, and includes more specifically: the rated capacity, model number, installation location, installation angle, orientation, amount of wear and tear of the solar panels included in the solar generator, and years passed since installation; the amount of sunlight radiated on the solar panels that is blocked by an obstruction; and the amount of wear and tear, and years passed since installation of a power conditioner included in the solar generator. Electric generator-related data 16 is obtained from the specifications, installation mode, time passed since installation, and the like of the solar generator.

Note that weather data 12, solar radiation data 14, and electric generator-related data 16 may further contain future data when the future data can be inferred from current and past data.

Electrical output estimation unit 20 is a processing unit that estimates the electrical output of the solar generator generated by one phenomenon at an amount indicated by the one of the plurality of physical quantities contained in memory unit 10. Electrical output estimation unit 20 acquires the physical quantities contained in memory unit 10 at a specific point in time (for example, the present time, a point in time in the past, or a point in time in the future), and estimates the electrical output of the solar generator at the above specific point in time based on the acquired physical quantities. Electrical output estimation unit 20, for example, acquires the cloudiness, humidity, and insolation at the present time from memory unit 10 as the above physical quantities, and estimates the electrical output at the present time using this information. Note that electrical output estimation unit 20 can not only estimate the electrical output at the above point in time using the cloudiness, humidity, and insolation from a point in time in the past, but also when memory unit 10 contains weather data 12 and the like at a point in time in the future. Electrical output estimation unit 20 may use conventional techniques to estimate the electrical output. Note that electrical output estimation unit 20 corresponds to an acquiring unit, electrical output assessment unit, and prediction unit.

Index calculation unit 30 is a processing unit that acquires the standard electrical output, which is the electrical output of the solar generator assuming the above phenomenon occurs at a predetermined amount, and calculates the indices (also referred to as assessment values) of the electrical output estimated by electrical output estimation unit 20 with respect to the standard electrical output. Here, the predetermined amount of the phenomenon may indicate the phenomenon as not occurring at all, and may also be set as an average amount at which the phenomenon occurs. For example, the physical quantity cloudiness can be set at a predetermined amount of 0% which indicates that there are no clouds covering the sky whatsoever. In this case, the solar generator produces the maximum possible electrical output within a fluctuation range that is dependent on the magnitude of the influence of the cloudiness. Moreover, when the cloudiness is more than 0%, the solar generator produces an electrical output less than the maximum electrical output.

Moreover, the physical quantity humidity can be set at a predetermined amount of a suitable standard value (for example, 40%). Moreover, the information indicating in which of the plurality of subdivisions of the electrical output, for which the standard electrical output is set as the upper limit, the electrical output estimated by electrical output estimation unit 20 is included can, for example, be used for the indices. Here, the standard electrical output is defined as the maximum electrical output within the fluctuation range dependent on one phenomenon. Note that the range of each of the subdivisions is determined beforehand, and may all be identical or different from each other. Moreover, determining in which of the plurality of subdivisions the electrical output estimated by electrical output estimation unit 20 is included is also referred to as rating scale assessment.

Moreover, index calculation unit 30 generates information indicating the calculated indices (to be specific, image or audio information), and provides the generated information to presentation unit 40.

Note that index calculation unit 30 may also calculate as indices the numerical values that grow larger as the electrical output estimated by electrical output estimation unit 20 increases or decreases for phenomena that cause the electrical output of the solar generator to respectively increase or decrease as their amounts grow larger. By being able to show the amount relationship of the phenomena and the quantity relationship of the indices, the user can intuitively understand how large the amount of the phenomena is using the indices.

Note that index calculation unit 30 can also calculate indices without using the estimated electrical output. In this case, index calculation unit 30 calculates the indices of the insolation, humidity, and cloudiness using a threshold value thereof determined beforehand. In this manner, similar to electrical output estimation unit 20, index calculation unit 30 determines in which of the plurality of subdivisions determined beforehand the insolation, humidity, and cloudiness are included (also referred to as the rating scale assessment). Note that index calculation unit 30 corresponds to the acquiring unit, weather assessment unit, and information generation unit.

Moreover, index calculation unit 30 should set a threshold value for every specific area. The specific areas may indicate solar generator installations, municipalities, prefectures, or areas where electricity retailers operate.

Presentation unit 40 is a processing unit that presents indices calculated by index calculation unit 30. Presentation unit 40 is, for example, a display device that presents information on its display screen by displaying an image, and hereinafter, presentation unit 40 will be described as such, but a speaker and the like may also be used for presenting information with audio.

Note that presentation device 1 can operate by computing equipment, such as a personal computer, server, smartphone, tablet, or smartwatch executing a predetermined program. In this case, memory unit 10 is, for example, memory (not illustrated in the drawings) and the like included in the computing equipment. Processing units such as electrical output estimation unit 20 and index calculation unit 30 are processors (not illustrated in the drawings) and the like executing a predetermined program.

The process of presentation device 1 will be described in detail next.

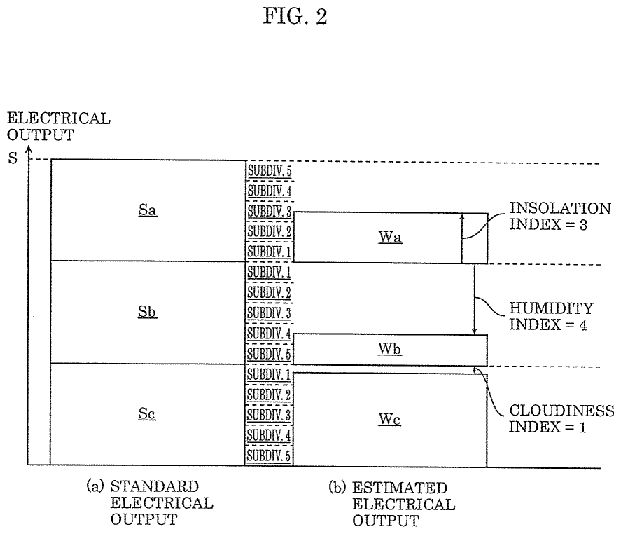

FIG. 2 is an explanatory diagram showing an example of the index calculation method by index calculation unit 30 according to the present embodiment. Note that the index calculation method illustrated here is a mere example and that it is possible to use other methods.

In (a) of FIG. 2, standard electrical output S is shown which is the electrical output of the solar generator assuming the phenomena occur at a predetermined amount. Standard electrical output S is, for example, the electrical output under conditions in which the solar generator is presumably capable of producing the maximum possible electrical output within its fluctuation range which is dependent on the influence of the insolation, humidity, and cloudiness. More specifically, standard electrical output S indicates, for example, the electrical output at noon during the summer solstice.

In (a) of FIG. 2, electrical outputs Sa, Sb, and Sc, which are the items of standard electrical output S, are also illustrated. Electrical outputs Sa, Sb, and Sc are derived using coefficients ka, kb, and kc as stated below. Standard electrical output S is considered to be influenced by the insolation, humidity, and cloudiness, and is represented by (Expression (Expr.) 1) below. Here, the humidity and cloudiness are expressed as percentages. Moreover, coefficients ka, kb, and kc each indicate the rate of change of the electrical output with respect to a corresponding one of (i) an inclined insolation, (ii) a product of the inclined insolation and humidity, and (iii) a product of the inclined insolation and cloudiness.

Standard electrical output S=rated capacity×inclined insolation×(ka+kb×(100−humidity)+kc×(100−cloudiness)) (Expr. 1)

Standard electrical output S is represented in (Expr. 2) to (Expr. 5) as the sum of portion Sa caused to fluctuate by only the insolation, portion Sb caused to fluctuate by the insolation and humidity, and portion Sc caused to fluctuate by the insolation and cloudiness.

S=Sa+Sb+Sc (Expr. 2)

Here,

Sa=rated capacity×inclined insolation×ka (Expr. 3)

Sb=rated capacity×inclined insolation×kb×(100−humidity) (Expr. 4)

Sc=rated capacity×inclined insolation×kc×(100−cloudiness) (Expr. 5)

Moreover, in (b) of FIG. 2, the estimate value (estimated electrical output) of the actual electrical output during a specific point in time is illustrated as W. The estimated electrical output indicates the estimated electrical output of the solar generator with an insolation, humidity, and cloudiness during a specific point in time. In (b) in FIG. 2, the items electrical outputs Wa, Wb, and We of estimated electrical output W are also illustrated. The relationships between estimated electrical output W and electrical outputs Wa, Wb, and We are the same as the relationships between standard electrical output S and electrical outputs Sa, Sb, and Sc ((Expr. 2) to (Expr. 5)), and description thereof is omitted.

Index calculation unit 30 calculates indices using the standard electrical output and estimated electrical output as stated below. For example, index calculation unit 30 calculates the numerical values indicating in which of the five subdivisions of the electrical output estimated electrical outputs Wa, Wb, and We are included as indices pertaining to the insolation (hereafter also referred to as “insolation indices”). In the example of FIG. 2, estimated electrical output Wa is included in the third subdivision from the bottom (subdivision 3), and as such, the insolation index is calculated as 3. Moreover, estimated electrical output Wb is included in the fourth subdivision from the top (subdivision 4), and as such, the humidity index is calculated as 4. The same applies to the cloudiness index, and is calculated as 1. Note that the order of the subdivisions of the insolation index mentioned above being opposite to the order of the subdivisions of the humidity index and the cloudiness index is caused by the amount relationships of the phenomena and electrical output also being opposite to each other.

Presentation modes of presentation unit 40 will be described next.

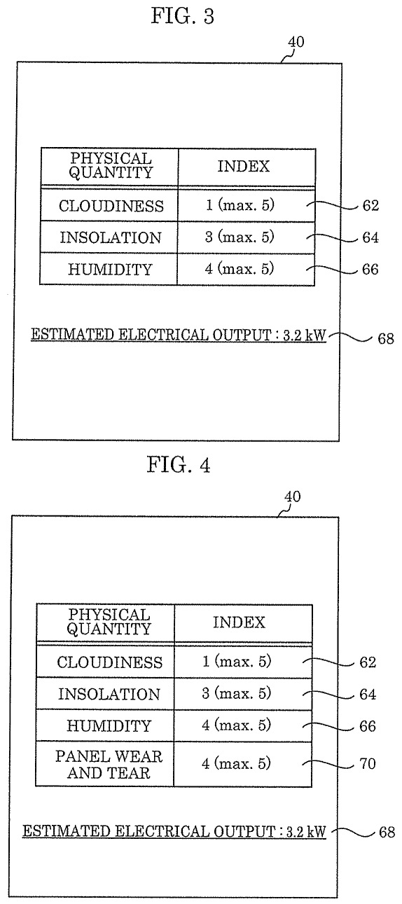

FIG. 3 is an explanatory diagram showing a first mode of an index presentation by presentation unit 40 according to the present embodiment. Presentation unit 40 illustrated in FIG. 3 presents cloudiness index 62, insolation index 64, and humidity index 66 calculated by index calculation unit 30.

For example, since cloudiness index 62 is output as 1 in the example of FIG. 2, cloudiness index 62 is displayed as 1 in FIG. 3. Note that for cloudiness index 62, presentation device 40 need not only display the numerical value indicating the subdivision, but may also display the total number of subdivisions as “(max. 5)”. Since the total number of subdivisions is also displayed, the user can understand where the numerical value indicating the subdivision is located with respect to the total number of subdivisions. The user, therefore, has the advantage of being able to intuitively understand how much the cloudiness influences the electrical output at a specific point in time.

Assuming that this index is indicated by the absolute value of the cloudiness (for example, displaying “10%”), the user can only understand the cloudiness at a specific point in time and not how much the cloudiness influences the electrical output at a specific point in time. The user, however, cannot understand which and how much the phenomena influence the electrical output of the solar generator at a specific point in time. More specifically, when the electrical output at a specific point in time is, for example, only approximately half of the rated capacity of the electric generator, the user cannot obtain the information that forms a basis for determining whether this is due to the cloudiness, insolation, or humidity.

The index of the estimated electrical output taking the cloudiness into account (cloudiness index 62) indicates how much the cloudiness influences the electrical output at a specific point in time. In other words, this information forms a basis for determining what contributes to the electrical output at a specific point in time. By being presented this index, the user can intuitively understand how much the cloudiness influences the electrical output at a specific point in time.

Insolation index 64 and humidity index 66 are respectively calculated by index calculation unit 30 from the insolation and humidity, and the same applies as with cloudiness index 62. As such, detailed description thereof is omitted.

Moreover, presentation unit 40 may also display estimated electrical output 68 estimated by electrical output estimation unit 20. By being presented estimated electrical output 68 along with cloudiness index 62 and the like, the user can simultaneously see the amount of estimated electrical output 68 and each index, and has the advantage of being able to understand intuitively how much each physical quantity influences the electrical output at a specific point in time.

FIG. 4 is an explanatory diagram showing a second mode of the index presentation by presentation unit 40 according to the present embodiment. Presentation unit 40 illustrated in FIG. 4 presents cloudiness index 62, insolation index 64, humidity index 66, and panel wear and tear index 70 calculated by index calculation unit 30. Note that objects identical to objects illustrated in FIG. 3 have the same reference numerals, and as such, detailed description thereof is omitted.

Panel wear and tear index 70 is the amount of wear and tear on the solar panels included in the solar generator calculated by index calculation unit 30. A comparison of panel wear and tear index 70 and fluctuations over time in the cloudiness index, insolation index, or humidity index shows that the fluctuations are comparatively small. However, by presenting panel wear and tear index 70 along with cloudiness index 62 and the like, the user can simultaneously see the amount of estimated electrical output 68 and panel wear and tear index 70, and can also intuitively understand how much each physical quantity influences the electrical output at a specific point in time.

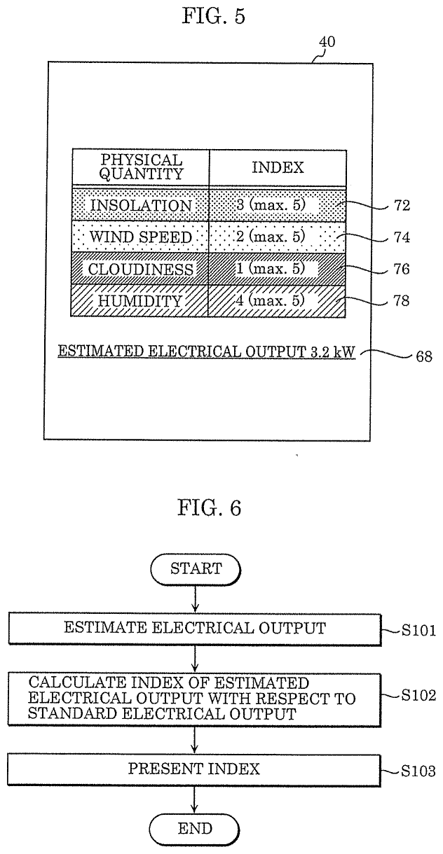

FIG. 5 is an explanatory diagram showing a third mode of the index presentation by presentation unit 40 according to the present embodiment. Presentation unit 40 illustrated in FIG. 5 presents insolation index 72, wind speed index 74, cloudiness index 76, and humidity index 78 calculated by index calculation unit 30. The numerical values of these indices are the same as those illustrated in FIGS. 3 and 4, and as such, description thereof is omitted.

Presentation unit 40 illustrated in FIG. 5 is characterized by the presentation mode of the above indices. To be specific, presentation unit 40 is characterized by the display colors in the table where the indices are presented and the color strengths.

The display colors of the indices are dependent on the directionality of the indices influencing the electrical output. In other words, presentation unit 40 presents on the display screen with different display modes (i) the indices of phenomena that cause the electrical output of the solar generator to increase as their amounts grow larger, and (ii) the indices of phenomena that cause the electrical output of the solar generator to decrease as their amounts grow larger.

To be specific, presentation unit 40 displays the indices with display colors for which the electrical output of the solar generator increases as the amount of the phenomena corresponding to the indices grows larger (insolation and wind speed in FIG. 5), with colors that the user associates with the sun, solar radiation, or warmth (for example, warm colors such as red, yellow, or orange).

However, presentation unit 40 displays the display colors of the indices for which the electrical output of the solar generator decreases as the amount of the phenomena corresponding to the indices grows larger (cloudiness and humidity in FIG. 5), with colors that the user associates with the opposite of the sun, solar radiation, or the like (for example, cool colors such as blue, purple, or gray). The user can hereby intuitively understand the directionality of the indices influencing the electrical output according to these display colors.

Moreover, the display colors are darker as the indices grow larger. For example, an insolation index of 5 is displayed with a comparatively deep red, and an insolation index of 1 is displayed with a comparatively light red. The user can hereby intuitively understand how much the indices influence the electrical output through the color strengths of these display colors.

A control method of presentation device 1 as configured above will be described.

FIG. 6 is a flowchart showing a control method of presentation device 1 according to the present embodiment. It is assumed that at when the control method in FIG. 6 commences, memory unit 10 contains the plurality of physical quantities indicating the respective amounts of the plurality of phenomena that cause the electrical output the of the solar generator to change.

In step S101 (electrical output estimation step), electrical output estimation unit 20 retrieves the plurality of physical quantities indicating the respective amounts of the plurality of phenomena that cause the electrical output of the solar generator to change contained in memory unit 10, and estimates the electrical output of the solar generator resulting from one phenomenon at an amount indicated by the one of the plurality of physical quantities.

In step S102 (index calculation step), index calculation unit 30 acquires the standard electrical output, which is the electrical output of the solar generator assuming the above phenomenon occurs at a predetermined amount, and calculates the index of the electrical output estimated in electrical output estimation unit step with respect to the standard electrical output.

In step S103 (presentation step), presentation unit 40 presents the index calculated in the index calculation step.

Note that a program for causing a computer to execute the above control method is also included in the scope of the present invention.

This control method makes it possible to present information that forms a basis to determine the validity of the electrical output of the solar generator.

### Variation 1 of Embodiment

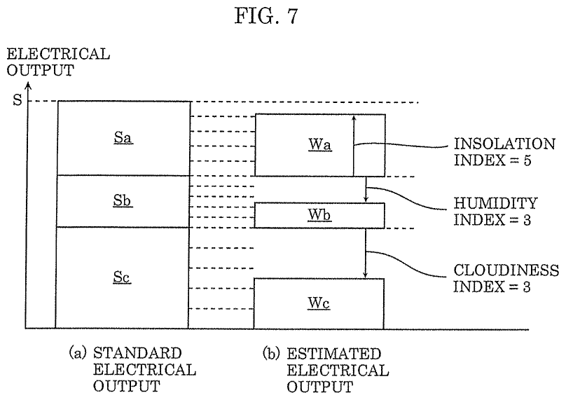

Next, a variation of the index calculation method will be described. An issue that may result from the index calculation method of the above embodiment will first be described with reference to FIG. 7.

FIG. 7 is an explanatory diagram showing a different example of the index calculation method by index calculation unit 30 according to the present embodiment.

FIG. 7 shows the insolation index, cloudiness index, and humidity index when estimated by index calculation unit 30 as 5, 3, and 3, respectively. Here, since standard electrical output Sb is lower than standard electrical output Sc, the humidity index and cloudiness index are calculated as having the same values regardless of estimated electrical output Wb being smaller than estimated electrical output Wc.

When presented with the humidity index and cloudiness index calculated in this way, the user can understand that the humidity and cloudiness influence the electrical output at a specific point in time to a substantially equal degree. Although this understanding is correct in part, a misunderstanding may occur when there is no significant difference between estimated electrical outputs Wb and Wc. An index calculation method for avoiding such a misunderstanding beforehand will be described below.

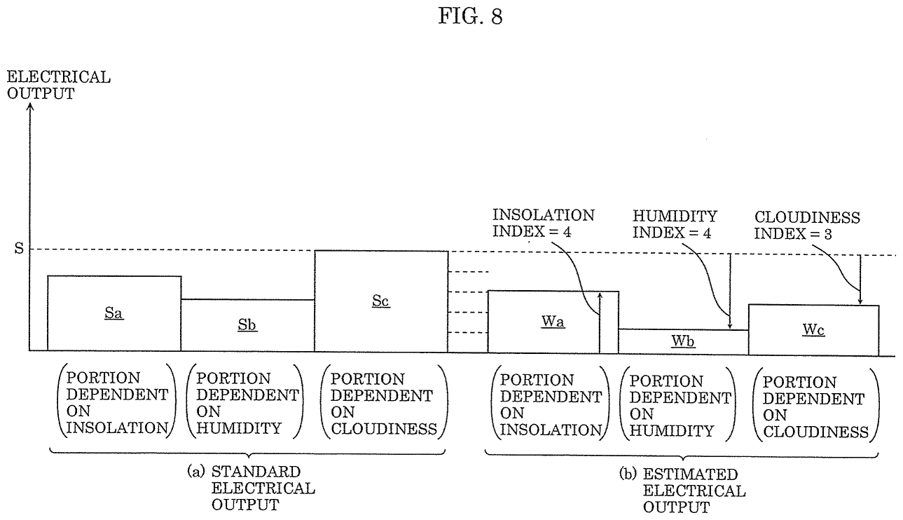

FIG. 8 is an explanatory diagram showing the index calculation method by index calculation unit 30 according to Variation 1.

In this variation, index calculation unit 30 calculates the indices using (i) standard electrical output Sc, which is the highest of standard electrical outputs Sa, Sb, and Sc, and (ii) the estimated electrical output of each index. For example, index calculation unit 30 calculates as the insolation index the numerical value indicating in which of the five subdivisions of the electrical output, for which standard electrical output Sc is set as the upper limit, estimated electrical output Wa is included. In the example of FIG. 8, estimated electrical output Wa is included in the fourth subdivision from the bottom (subdivision 4), and as such, the insolation index is calculated as 4.

The same applies to the humidity index and cloudiness index, and are respectively calculated as 4 and 3 based on subdivisions including estimated electrical outputs Wb and Wc. The order of the subdivisions is the same as the order described for FIG. 2.

In this manner, the humidity index and cloudiness index are respectively calculated as 4 and 3. The possibility of a misunderstanding when there is no significant difference between estimated electrical outputs Wb and We can thus be avoided beforehand.

### Variation 2 of Embodiment

Next, a variation of the index calculation method will be described. This calculation method not only takes into consideration each index, such as the insolation index and cloudiness index, but also the influence of each index on the other indices (hereinafter also referred to as “mutual influence”). With this, presentation device 1 can present how much the plurality of indices influence one another to the user.

In Variation 2, memory unit 10 contains the physical quantities indicating the amounts of the phenomena.

Electrical output estimation unit 20 estimates a first electrical output, which is the electrical output of the solar generator produced by the phenomena at amounts indicated by the plurality of physical quantities. Moreover, electrical output estimation unit 20 estimates a second electrical output, which is the electrical output of the solar generator produced by both (i) the phenomena at amounts indicated by the physical quantities and (ii) the phenomena at amounts indicated by the physical quantities excluding one of the plurality of physical quantities.

Index calculation unit 30 calculates the indices of both the first electrical output and the second electrical output estimated by electrical output estimation unit 20 relative to the standard electrical output.

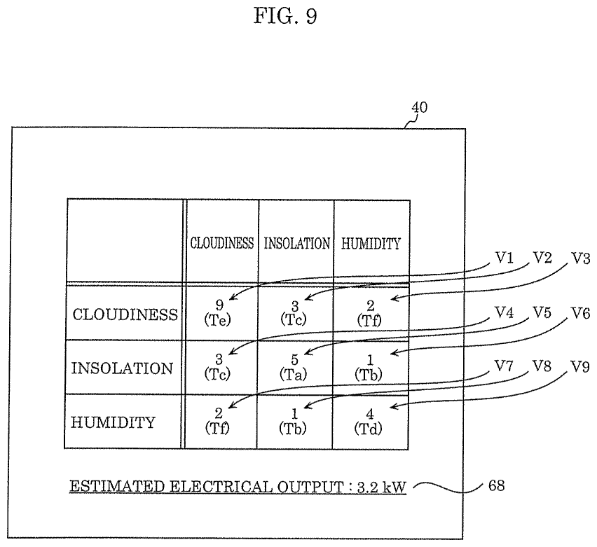

FIG. 9 is an explanatory diagram showing a mode of the index presentation by presentation unit 40 according to the present variation.

Index calculation unit 30 calculates the standard electrical output with below (Expr. 6), instead of above (Expr. 1).

Standard electrical output T=rated capacity×(inclined insolation×(ka+kb×(100−humidity)+kc×(100−cloudiness))+kd×(100−humidity)+ke×(100−cloudiness)+kf×(100−humidity)×(100−cloudiness) (Expr. 6)

Here, standard electrical output T is represented in (Expr. 7) to (Expr. 13) as the sum of (i) the portion caused to fluctuate by only one of the insolation, humidity, and cloudiness, and (ii) the portion caused to fluctuate by two of the insolation, humidity, and cloudiness.

T=Ta+Tb+Tc+Td+Te+Tf (Expr. 7)

Here,

Ta=rated capacity×inclined insolation×ka (Expr. 8)

Tb=rated capacity×inclined insolation×kb×(100−humidity) (Expr. 9)

Tc=rated capacity×inclined insolation×kc×(100−cloudiness) (Expr. 10)

Td=rated capacity×kd×(100−humidity) (Expr. 11)

Te=rated capacity×ke×(100−cloudiness) (Expr. 12)

Tf=rated capacity×kf×(100−humidity)×(100−cloudiness) (Expr. 13)

Here, Ta, Td, and Te respectively indicate how much the insolation, humidity, and cloudiness influence the electrical output at a specific point in time. Tb indicates how much the insolation and humidity influence the electrical output at a specific point in time. Tc indicates how much the insolation and cloudiness influence the electrical output at a specific point in time. Tf indicates how much the humidity and cloudiness influence the electrical output at a specific point in time.

Moreover, coefficients ka, kb, kc, kd, ke, and kf each indicate the rate of change of the electrical output with respect to a corresponding one of the inclined insolation, the product of the inclined insolation and humidity, the product of the inclined insolation and cloudiness, the humidity, the cloudiness, and the product of the humidity and cloudiness.

Presentation unit 40 presents indices Ta to Tf, calculated as described above, with the mode illustrated in FIG. 9.

In FIG. 9, the cloudiness index, insolation index, and humidity index are laid out vertically and horizontally, and the indices along both directions indicate how much the indices influence the electrical output at a specific point in time.

Here, the indices of the same physical quantities along both directions, i.e., values V1, V5, and V9 in FIG. 9 are respectively the cloudiness index, insolation index, and humidity index. The indices of different physical quantities along both directions, i.e., values V2, V3, V4, V6, V7, and V8 indicate how much the mutual influence between the indices along the vertical direction and the indices along the horizontal direction influence the electrical output at a specific point in time. For example, value V2 indicates how much the mutual influence between the cloudiness and insolation influences the electrical output.

In the example illustrated in FIG. 9, the influences of the cloudiness alone (i.e., the cloudiness index), the cloudiness and insolation, and the cloudiness and humidity are respectively displayed as 9, 3, and 2. In this manner, with the presentation for which the indices are taken into account, the user has the advantage of being able to comprehend the magnitude of the mutual influence between the indices.

### Variation 3 of Embodiment

Next, two example modes of the index presentation different from those in the above embodiment will be described. The first example presents the indices with illustrations and the second example with panels.

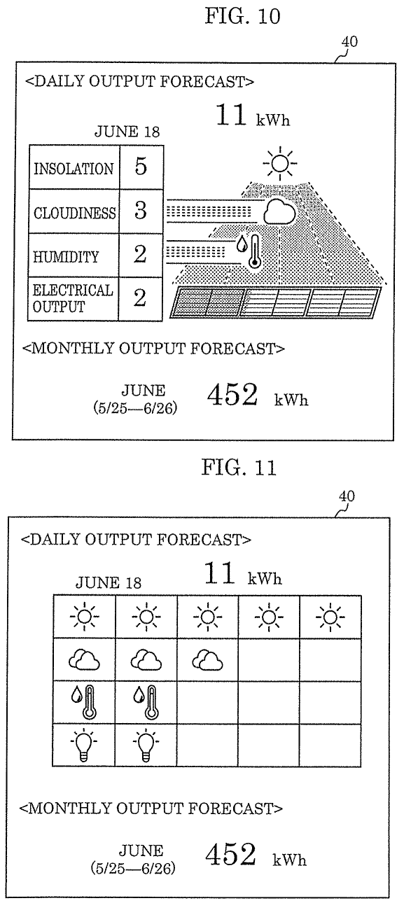

FIG. 10 is an explanatory diagram showing a presentation mode using index illustrations by presentation unit 40 according to Variation 3. Presentation unit 40 presents the insolation index, cloudiness index, and humidity index calculated by index calculation unit 30 as illustrations.

Here, the illustrations of the insolation index, cloudiness index, and humidity index are characterized by being displayed from top to bottom on the display screen. Moreover, the insolation index, cloudiness index, and humidity index are displayed as images that grow larger (images with a larger size) as the indices are higher. To be specific, the insolation index is represented with a number of dashed lines coming from the sun, and the cloudiness index and humidity index are each represented with illustrations extending from the left to the right.

The order of each index is the same as the order of the sun, clouds, and the living environment of people in the natural world. A portion of the solar radiation from the sun is blocked by clouds, a portion of the solar radiation not blocked by clouds is blocked due to the influence of the humidity in the living environment of people, and then the solar radiation reaches the solar panels. Thus, this succession of natural phenomena is reproduced as these illustrations.

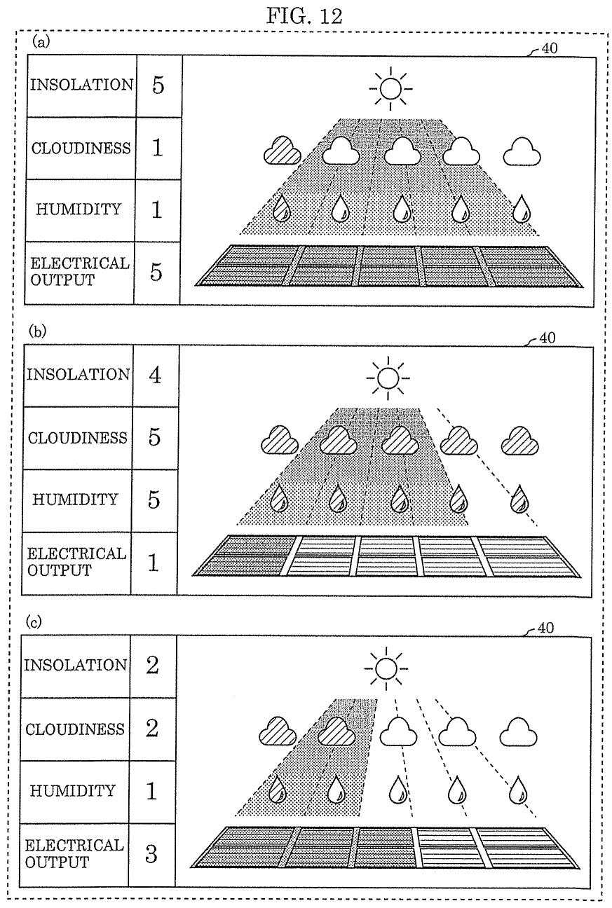

FIG. 11 is an explanatory diagram showing a presentation mode using index panels by presentation unit 40 according to the present variation. Presentation unit 40 presents the insolation index, cloudiness index, and humidity index calculated by index calculation unit 30 with a different presentation mode than that of FIG. 10. To be specific, in FIG. 11, presentation unit 40 presents the insolation index, cloudiness index, and humidity index calculated by index calculation unit 30 as rectangular panels lined up.

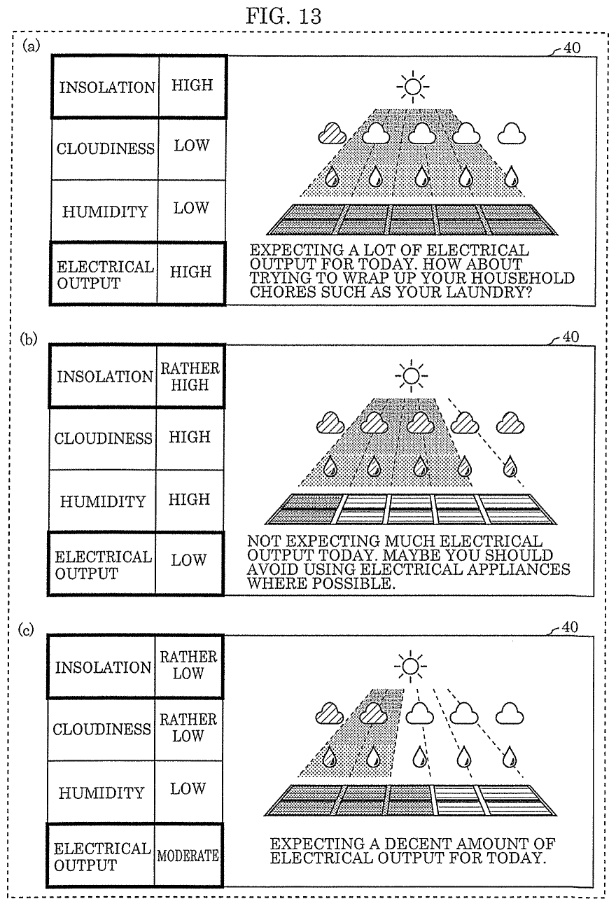

FIGS. 12 and 13 are explanatory diagrams showing concrete examples of the presentation mode using index illustrations by presentation unit 40 according to the present variation. Concrete examples of the insolation, cloudiness, and humidity and how the images thereof are presented by presentation unit 40 will be described with reference to FIG. 12.

Image (a) of FIG. 12 shows the indices of the insolation and the like, and the index of the electrical output on a clear day during any time besides winter. Because the insolation (5) is comparatively high, and the cloudiness (1) and humidity (1) comparatively low, the electrical output (5) is indicated comparatively high due to comparatively strong solar radiation reaching the solar generator without being blocked by clouds and the like. Moreover, since the above items are also represented by illustrations, the user has the advantage of easily and intuitively understanding the index of the electrical output.

Image (b) of FIG. 12 shows the indices of the insolation and the like, and the index of the electrical output on a day when the solar radiation is blocked by clouds or moisture. Because the insolation (4) is comparatively high, and the cloudiness (5) and humidity (5) are also comparatively high, the amount of light reaching the solar generator is indicated comparatively low due to the comparatively strong solar radiation being blocked by clouds and the like. The index of the electrical output is 1.

Image (c) of FIG. 12 shows the indices of the insolation and the like, and the index of the electrical output on a clear day in winter. Because the insolation (2) is moderate, and the cloudiness (2) and humidity (2) are moderate as well, the amount of light reaching the solar generator is indicated partially reduced due to the moderately strong solar radiation being blocked by clouds and the like. The index of the electrical output is 3.

In FIG. 12, the indices of the insolation, cloudiness, humidity, and the electrical output are represented with a numerical value from 1 to 5, but may also be represented with expressions like “low”, “rather low”, “moderate”, “rather high”, “high”, or “small”, “rather small”, “medium”, “rather large”, “large”, as illustrated in FIG. 13. Moreover, because the cloudiness and humidity block the solar radiation and reduce the electrical output, and the indices aside from the cloudiness and humidity, i.e., the insolation and electrical output, may be, for example, surrounded by a thick frame for emphasis.

Moreover, as illustrated in FIG. 13, the user may also be presented with advice relating to living activities and the like based on the indices of the insolation, cloudiness, humidity, and the electrical output.

In image (a) of FIG. 13, because the insolation and electrical output are comparatively high, the user can be encouraged to use the generated electricity efficiently to optimize the user's electric power balance by presenting the user with advice such as: “Expecting a lot of electrical output for today. How about trying to wrap up your household chores such as your laundry?”

In image (b) of FIG. 13, because the insolation is comparatively high, and so are the cloudiness and humidity, a large portion of the solar radiation is blocked and the index of the electrical output is low, so the user can be encouraged to use the generated electricity efficiently to optimize the user's electric power balance by presenting the user with advice such as: “Not expecting much electrical output today. Maybe you should avoid using electrical appliances where possible.”

In image (c) of FIG. 13, the insolation is moderate, and so is the index of the electrical output, so the user may be presented with a qualitative phrase such as: “Expecting a decent amount of electrical output for today.”

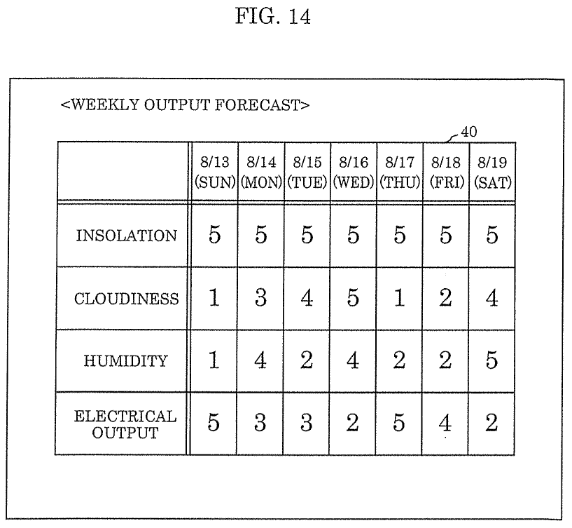

FIG. 14 is an explanatory diagram showing a presentation mode using an index calendar by presentation unit 40 according to the present variation.

As illustrated in FIG. 14, by presenting the user with daily updates of the indices of the insolation, cloudiness, humidity and the electrical output over a fixed period of one week, two weeks, or one month, the user can check the indices to plan the user's living activities and the like.

The placement order of the insolation index, cloudiness index, and humidity index panels are the same as the order of the above illustrations. By displaying the indices using panels, the user has the advantage of more clearly being conveyed the magnitude of each index.

By using this presentation mode, the user has the advantage of being able to intuitively understand what influences the estimated electrical output in line with the succession of natural phenomena. Assuming that the sun is placed under the clouds, it is no longer possible to say that the natural phenomenon wherein a portion of the solar radiation from the sun is blocked by the clouds is reproduced, which is an inconvenient and difficult to understand display mode for the user.

Note that when there is an intuitive understanding by the user, the user has the advantage of being capable of, for example, considering the possibility of malfunctions in the solar panels when the present actual electrical output is significantly lower than the present estimated electrical output, and considering ways to obtain a higher electrical output.

### Variation 4 of Embodiment

Next, the presentation device according to the above embodiment configured as a presentation system including a plurality of devices will be described.

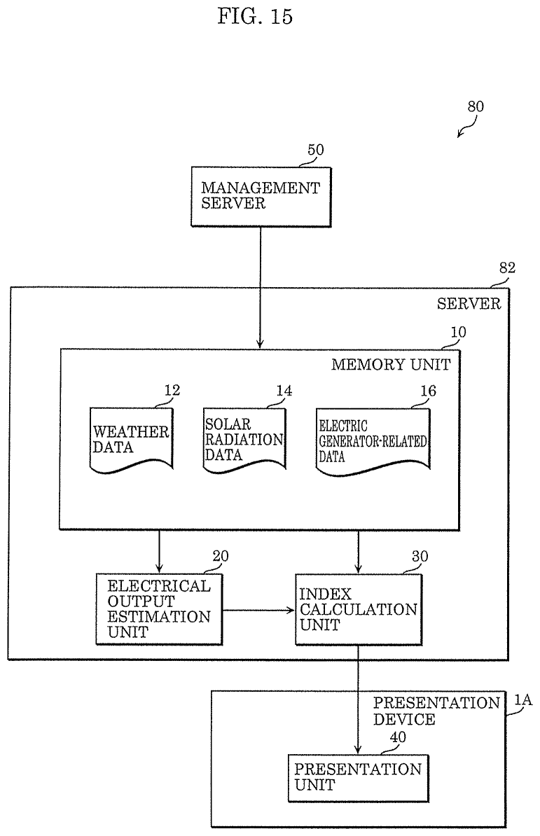

FIG. 15 is a block diagram showing the function blocks of presentation system 80 according to Variation 4.

As illustrated in FIG. 15, presentation system 80 includes server 82 and presentation device 1A. Server 82 and presentation device 1A are communicably connected with a communication line, and include and divide the function blocks of presentation device 1 according to the above embodiment. The communication line may be any kind of line, and more specifically, a land line, mobile phone line, data communication line, or a network combining these.

To be specific, server 82 includes memory unit 10, electrical output estimation unit 20, and index calculation unit 30. Each of the above components has the same name as the components in the embodiment, and as such, description thereof is omitted.

Presentation device 1A also includes presentation unit 40. Presentation unit 40 is the same as presentation unit 40 according to the embodiment, and as such, description thereof is omitted.

Above server 82 and presentation device 1A exhibit the same functions as presentation device 1 according to Embodiment 1. Note that dividing the functions between server 82 and presentation device 1A may also apply to the other modes described above. To be specific, for example, only one of or both electrical output estimation unit 20 and index calculation unit 30 may be included in presentation device 1A.

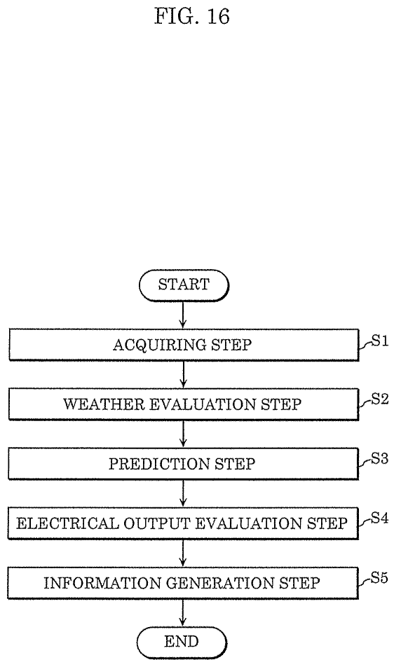

FIG. 16 is a flowchart showing an example of a process of presentation system 80 according to the present variation.

In step S1 (acquiring step), server 82 acquires weather information relating to at least one of the plurality of physical quantities including the insolation, cloudiness, and humidity. Weather data 12 relating to the cloudiness and humidity, and solar radiation data 14 relating to the insolation are acquired from a servicer providing weather data or management server 50 and the like that manage data provided by the servicer.

In step S2 (weather evaluation step), server 82 performs a rating scale assessment of the weather information based on a predetermined threshold value.

In step S3 (prediction step), server 82 predicts the electrical output of the solar generator.

In step S4 (electrical output evaluation step), server 82 performs a rating scale assessment of the electrical output of the solar generator based on the standard electrical output of the solar generator

In step S5 (information generation step), server 82 generates information indicating an assessment value obtained from the rating scale assessment in the weather evaluation step, and an assessment value obtained from the rating scale assessment in the electrical output evaluation step. Here, the generated information is, for example, an image or audio, but is not limited thereto. The information generated in this manner may be, for example, provided to presentation device 1A and presented by presentation device 1A (presentation unit 40). Presentation unit 40 displays images on a display screen when the generated information is in the form of images, and outputs audio through a speaker when the generated information is in the form of audio.

This enables presentation system 80 to present information that forms a basis to determine the validity of the electrical output of the solar generator. Note that this process flow is also applicable to the embodiment and each of the variations.

Hereinafter, a configuration, advantageous effects, and the like of presentation device 1 according to a mode of the present invention will be described.

The method according to a mode of the present invention includes: acquiring weather information relating to at least one of physical quantities including insolation, cloudiness, and humidity (step S1); performing the rating scale assessment of the weather information based on the predetermined threshold value (step S2); predicting the electrical output of the solar generator (step S3); performing the rating scale assessment of the electrical output of the solar generator based on the standard electrical output of the solar generator (step S4); and generating information indicating the assessment value obtained in the performing of the rating scale assessment of the weather information, and the assessment value obtained in the performing of the rating scale assessment of the electrical output (step S5).

Presentation device 1 presents the user with the assessment value that indicates how much the phenomena that can change the electrical output of the solar generator influence this electrical output. The user can intuitively understand what kind of phenomena influence the electrical output of the solar generator by being presented with this assessment value. In this manner, presentation device 1 makes it possible to present information that forms a basis to determine the validity of the electrical output of the solar generator.

The user can, for example, be presented with information for determining why the estimated electrical output is less (or larger) than expected. Supposing that the user cannot acquire information indicating what kind of phenomena influence the estimated electrical output, the user is unable to concretely determine how to improve the electrical output and may take the wrong actions. The user may end up taking actions that are not necessarily linked to an improvement of the electrical output, such as replacing the solar generator in order to improve the electrical output in a situation where the estimated electrical output is low due to a high amount of cloudiness. Accordingly, presentation device 1 can encourage the user to take appropriate action to improve the electrical output by presenting information that forms a basis to determine the validity of the electrical output of the solar generator.

In the step for generating information, the information indicating an assessment value obtained from the rating scale assessment in the performing of the rating scale assessment of the weather information may also be an image that grows larger as the assessment value increases.

The size of the assessment value presented by presentation device 1 matches the dimensions of the image. The user can therefore more intuitively understand the assessment value through the presented image.

In the step for generating information, the information indicating the assessment value obtained from the rating scale assessment in the performing of the rating scale assessment of the weather information may also be an image that grows darker as the assessment value increases.

The size of the assessment value presented by presentation device 1 matches the color contrast of the image. The user can therefore more intuitively understand the assessment value through the color depth of the presented image.

Moreover, server 82 according to a mode of the present invention includes: the acquiring unit configured to acquire weather information relating to at least one of physical quantities including insolation, cloudiness, and humidity (a mode of electrical output estimation unit 20 and a mode of index calculation unit 30); a weather assessment unit configured to perform the rating scale assessment of the weather information based on the predetermined threshold value (a mode of index calculation unit 30); the prediction unit configured to predict the electrical output of the solar generator (a mode of electrical output estimation unit 20); the electrical output assessment unit configured to perform the rating scale assessment of the electrical output of the solar generator based on the standard electrical output of the solar generator (a mode of electrical output estimation unit 20); and the information generation unit configured to generate information indicating the assessment value obtained from the rating scale assessment performed by the weather assessment unit, and the assessment value obtained from the rating scale assessment performed by the electrical output assessment unit (a mode of index calculation unit 30).

Presentation device 1 produces similar results as described above.

Moreover, the program according to a mode of the present invention causes a computer to execute the method.

Presentation device 1 produces similar results as described above.

Moreover, the terminal (presentation device 1) according to a mode of the present invention includes: the acquiring unit configured to acquire weather information relating to at least one of physical quantities including insolation, cloudiness, and humidity (a mode of electrical output estimation unit 20 and a mode of index calculation unit 30); a weather assessment unit configured to perform the rating scale assessment of the weather information based on the predetermined threshold value (a mode of index calculation unit 30); the prediction unit configured to predict the electrical output of the solar generator (a mode of electrical output estimation unit 20); the electrical output assessment unit configured to perform the rating scale assessment of the electrical output of the solar generator based on the standard electrical output of the solar generator (a mode of electrical output estimation unit 20); and the information generation unit configured to generate information indicating the assessment value obtained from the rating scale assessment performed by the weather assessment unit, the assessment value obtained from the rating scale assessment performed by the electrical output assessment unit (a mode of index calculation unit 30); and presentation unit 40 configured to present the information generated by the information generation unit.

The terminal produces similar results as described above.

Moreover, presentation device 1 according to a mode of the present invention for generating information relating to the electrical output the solar generator includes: memory unit 10 that contains the plurality of physical quantities indicating respective amounts of the plurality of phenomena that cause the electrical output of the solar generator to change; electrical output estimation unit 20 that estimates the electrical output of the solar generator generated by one phenomenon at an amount indicated by the one of the plurality of physical quantities; index calculation unit 30 that acquires the standard electrical output, which is the electrical output of the solar generator assuming the above phenomenon occurs at a predetermined amount, and calculates the indices (also referred to as assessment values) of the electrical output estimated by electrical output estimation unit 20 with respect to the standard electrical output; and presentation unit 40 that presents indices calculated by index calculation unit 30.

Presentation device 1 presents the user with an index that indicates how much the phenomena that can change the electrical output of the solar generator influence this electrical output. This index does not directly indicate the amount of these phenomena, but how much the phenomena influence the electrical output. The user can intuitively understand what kind of phenomena influence the electrical output of the solar generator by being presented with this index. In this manner, presentation device 1 makes it possible to present information that forms a basis to determine the validity of the electrical output of the solar generator.

Index calculation unit 30 may also calculate the information that indicates in which of the plurality of subdivisions the electrical output estimated by electrical output estimation unit 20 is included as the above index.

Presentation device 1 presents in which of the plurality of subdivisions, for which the standard electrical output is set as the upper limit, the estimated electrical output is included. The user can more intuitively understand what kind of phenomena influence the estimated electrical output of the solar generator the presented information is in the form of subdivisions.

Index calculation unit 30 may also calculate as the above index the numerical values that grow larger as the electrical output estimated by electrical output estimation unit 20 increases or decreases for phenomena that cause the electrical output of the solar generator to respectively increase or decrease as their amounts grow larger.

The numerical value indicating the index presented by presentation device 1 matches the amount of the phenomena. The user can therefore more intuitively understand the amount of the phenomena through the presented index.

Presentation unit 40 may also present the index by displaying the index on a screen using an image that grows larger as the index calculated by index calculation unit 30 increases.

The size of the image indicating the index presented by presentation device 1 matches the amount of the estimated electrical output. The user can therefore more intuitively understand the amount of the electrical output through the presented index.

Presentation unit 40 may also present the index by displaying the index on a screen using an image that grows darker as the index calculated by index calculation unit 30 increases.

The color contrast of the image indicating the index presented by presentation device 1 matches the amount of the estimated electrical output. The user can therefore more intuitively understand the amount of the electrical output through the presented index.

Presentation unit 40 may also present on the display screen with different display modes (i) the index of phenomena that cause the electrical output of the solar generator to increase as their amounts grow larger, and (ii) the index of phenomena that cause the electrical output of the solar generator to decrease as their amounts grow larger.

This makes it possible to display the directionality of the index influencing the electrical output through the presentation mode of the index presented by presentation device 1. The user can therefore more intuitively understand the amount of the electrical output through the presented index.

Electrical output estimation unit 20 estimates the first electrical output, which is the electrical output of the solar generator produced by the phenomena at amounts indicated by the plurality of physical quantities, and the second electrical output, which is the electrical output of the solar generator produced by both (i) the phenomena at amounts indicated by the physical quantities and (ii) the phenomena at amounts indicated by the physical quantities excluding one of the plurality of physical quantities. Index calculation unit 30 may also calculate the indices of both the first electrical output and the second electrical output estimated by electrical output estimation unit 20 relative to the standard electrical output.

Presentation device 1 presents the index indicating the mutual influence of the phenomena on the electrical output of the solar generator. The user can understand how large the mutual influence of the phenomena on the electrical output is.

Moreover, the plurality of physical properties includes the insolation, cloudiness, and humidity. Presentation device 1 may also display the indices corresponding to the insolation, cloudiness, and humidity on the display screen from top to bottom, respectively.

The user can therefore intuitively understand what influences the estimated electrical output in line with the succession of natural phenomena.

The plurality of physical properties in presentation device 1 may also include the cloudiness, humidity, insolation, temperature, wind speed, wind direction, precipitation rate, or atmospheric pressure.

Presentation device 1 can hereby concretely present the cloudiness, humidity, insolation, temperature, wind speed, wind direction, precipitation rate, or atmospheric pressure as the physical properties.

The plurality of physical properties in presentation device 1 may also include: the rated capacity, model number, installation location, installation angle, orientation, amount of wear and tear of the solar panels included in the solar generator, and years passed since installation; the amount of sunlight radiated on the solar panels that is blocked by an obstruction; and the amount of wear and tear, and years passed since installation of a power conditioner included in the solar generator.

Presentation device 1 can hereby concretely present the capacity, installation location, installation angle, orientation, amount of wear and tear of the solar panels included in the solar generator, and years passed since installation; the amount of sunlight radiated on the solar panels that is blocked by an obstruction; and the amount of wear and tear, and years passed since installation of a power conditioner included in the solar generator.

The control method according to a mode of the present invention is the control method of presentation device 1 for presenting information relating to the electrical output the solar generator, and includes: the electrical estimation step in which the plurality of physical quantities indicating the respective amounts of the plurality of phenomena that cause the electrical output of the solar generator to change contained in memory unit 10 are retrieved, and the electrical output of the solar generator resulting from one phenomenon at an amount indicated by the one of the plurality of physical quantities is estimated; the index calculation step in which the standard electrical output, which is the electrical output of the solar generator assuming the above phenomenon occurs at a predetermined amount, is acquired, and the index of the electrical output estimated in electrical output estimation unit step with respect to the standard electrical output is calculated; and the presentation step in which the index calculated in the index calculation step is presented.

Presentation device 1 produces similar results as described above.

Moreover, the program according to a mode of the present invention causes the computer to execute the above control method.

Presentation device 1 produces similar results as described above.

### Other

The presentation device and the like according to the present invention have been described based on the above embodiment, but the present invention is not limited thereto.

Additionally, embodiments resulting from variations of the above embodiment conceived by those skilled in the art, as well as embodiments resulting from partial combinations of components in the above embodiments are included within the present invention so long as they do not depart from the scope thereof.

### REFERENCE MARKS IN THE DRAWINGS

1, 1A Presentation device
20 Electrical output estimation unit
30 Index calculation unit
40 Presentation unit
82 Server

1. A method, comprising:
acquiring weather information relating to at least one of physical quantities including insolation, cloudiness, and humidity;
performing a rating scale assessment of the weather information based on a predetermined threshold value;
predicting an electrical output of a solar generator;
performing a rating scale assessment of the electrical output of the solar generator based on a standard electrical output of the solar generator; and
generating information indicating an assessment value obtained in the performing of the rating scale assessment of the weather information, and an assessment value obtained in the performing of the rating scale assessment of the electrical output.

2. The method according to claim 1, wherein in the generating,
the information indicating the assessment value obtained in the performing of the rating scale assessment of the weather information is an image that is larger as the assessment value increases.

3. The method according to claim 1, wherein in the generating,
the information indicating the assessment value obtained in the performing of the rating scale assessment of the weather information is an image that is darker as the assessment value increases.

4. A server, comprising:
an acquiring unit configured to acquire weather information relating to at least one of physical quantities including insolation, cloudiness, and humidity;
a weather assessment unit configured to perform a rating scale assessment of the weather information based on a predetermined threshold value;
a prediction unit configured to predict an electrical output of a solar generator;
an electrical output assessment unit configured to perform a rating scale assessment of the electrical output of the solar generator based on a standard electrical output of the solar generator; and
an information generation unit configured to generate information indicating an assessment value obtained from the rating scale assessment performed by the weather assessment unit, and an assessment value obtained from the rating scale assessment performed by the electrical output assessment unit.

5. A non-transitory computer-readable storage medium having stored thereon a program for causing a computer to execute the method according to claim 1.

6. A terminal, comprising:
an acquiring unit configured to acquire weather information relating to at least one of physical quantities including insolation, cloudiness, and humidity;
a weather assessment unit configured to perform a rating scale assessment of the weather information based on a predetermined threshold value;
a prediction unit configured to predict an electrical output of a solar generator;
an electrical output assessment unit configured to perform a rating scale assessment of the electrical output of the solar generator based on a standard electrical output of the solar generator;
an information generation unit configured to generate information indicating an assessment value obtained from the rating scale assessment performed by the weather assessment unit, and an assessment value obtained from the rating scale assessment performed by the electrical output assessment unit; and
a presentation unit configured to present the information generated by the information generation unit.
